(19) United States
(12) Patent Application Publication
(10) Pub. No.: US 2015/0108003 A1
(43) Pub. Date: Apr. 23, 2015

(54) METHOD FOR PRODUCING CERAMIC CIRCUIT BOARDS FROM CERAMIC SUBSTRATES HAVING METAL-FILLED VIAS

(71) Applicant: CeramTec GmbH, Plochingen (DE)

(72) Inventor: Dietmar Jaehnig, Bindlach (DE)

(73) Assignee: CeramTec GmbH, Plochingen (DE)

(21) Appl. No.: 14/397,675

(22) PCT Filed: Apr. 30, 2013
(86) PCT No.: PCT/EP2013/059012

§ 371 Date: Jan. 12, 2015

(30) Foreign Application Priority Data
May 2, 2012 (DE) 102012207283.7

(51) Int. Cl. H05K 3/24; H05K 1/11; H05K 3/02; H05K 1/03

(52) U.S. Cl. CPC H05K 3/241; H05K 1/0306; H05K 1/115; H05K 3/027; H05K 2201/09563
USPC 205/125

(57) ABSTRACT

A method for producing ceramic circuit boards from ceramic substrates having metal-filled vias. In order to be able to fill the vias by means of a single filling process, either a planar copper metallization is applied on one side to the ceramic substrate having vias by means of scren printing, or a copper film of 100-300 μm is bonded on one side to the ceramic substrate having vias in a DCB/DBC process and the vias are filled from the ceramic side by means of an electrogalvanic process in a copper bath by the deposition of copper.

The invention relates to a method for producing ceramic circuit boards from ceramic substrates having metal-filled vias.

Ceramic circuit board having completely metal-filled vias (diameter approx. 100-300 μm) can be produced according to the prior art by repeated filling of the vias in the ceramic substrate using templates and building up a surface metallization by means of a first screen printing, burning in and galvanic reinforcement to more than 100 μm. Vias cannot be filled completely with copper pastes by a single filling operation (via filling operation).

The object of the invention is to improve a method according to the preamble of claim 1 in such a way that the vias can be filled with a single filling operation.

This object is achieved by the fact that
either a planar copper metallization is applied to one side of the ceramic substrate having vias by means of screen printing, or a copper film of 100-300 μm is bonded to one side by the DCB/DBC method and
the vias are filled from the ceramic side by deposition of copper by means of an electro-galvanic process in a copper bath.

A voltage can be applied by applying the copper metallization or the copper film. It should be pointed out here that the copper metallization or the copper film covers the vias on one side. In the subsequent electrogalvanic process, a voltage is applied to the copper metallization or to the copper film in the copper bath, and the vias are filled from the ceramic side. The ceramic side refers to the side opposite the side having the copper metallization or the copper film. With this method, the vias can be filled in a single filling operation.

Two inventive variants of the method are described below.

In a first variant, after applying the copper metallization by screen printing, the copper metallization is partially covered by a electroplate resist and then the vias are filled by the electrogalvanic process in a copper bath while at the same time the exposed sections (which are not under the electroplate resist) are reinforced to a layer thickness of 50-100 μm and then the electroplate resist is removed chemically, and the thinner unreinforced sections, which have been provided with a screen printing and which were previously beneath the electroplate resist, are dissolved. In this way it is possible to produce any metallizations with any thicknesses. The vias are completely filled with copper.

In a second variant, after bonding the copper film and filling the vias, any protruding copper burrs are removed mechanically, for example by brushing, lapping or grinding, and then the ceramic substrates are completed by using the DCB/DBC method. Any metallizations with any thicknesses can also be produced by these method steps. The vias are completely filled with copper.

In a first variant, the sections that are provided with a screen printing are preferably dissolved using a mixture of HCl+FeCl₃.

The vias preferably have a diameter of 50 to 5000 μm and are preferably created by lasering.

In a refinement of the invention, it is provided in the electrogalvanic process that the ceramic substrate is rotated in the copper bath with the ceramic side facing the anode that is mounted in the galvanic basin and then is rinsed with electrolyte. This enormously improves the filling of the vias.

The mass exchange in the galvanic basin can be further improved by using vibration and/or ultrasound.

In the first variant of the invention, a copper metallization is applied by screen printing to one side of the ceramic substrate having the vias previously created by lasering, for example, but at the same time, the copper metallization is being forced into the vias in an uncontrolled manner. The coating thickness after burning in is usually 6-12 μm, the vias are metallized on the edges but are not hermetically sealed. Next the copper metallization is partially covered by a electroplate resist. The term “electroplate resist” is understood to refer to materials that are applied to the metallization or the copper film to prevent galvanic deposition in those locations where they cover the surface.

After applying the electroplate resist, the ceramic substrate is immersed in a copper bath, where the vias are allowed to close up due to deposition of copper in an electrogalvanic process, and the exposed sections (not covered by the electroplate resist) are reinforced to layer thicknesses of 50-100 μm. Then the electroplate resist is removed chemically (dissolved). The thin screen-printed sections are dissolved with a mixture of HCl+FeCl₃, for example. The thicker sections of the metallization are thinned only slightly. In the case of higher quality products, the galvanized layout may be protected by tinning or by a photoresist before stripping off the resist.

The second possibility and/or inventive variant consists of lasering vias into the ceramic substrates of all types and thicknesses and coating them with a copper film 100-300 μm thick by using the DCB/DBC method. The vias (diameter 50-5000 μm) may then be filled by the method described above. After filling, the protruding copper burrs are removed mechanically, for example, by brushing, lapping or grinding. The half substrates treated in this way may then be completed by using the DCB/DBC method and exhibit reliable vertical interconnect access.

For cathodic filling of the vias and reinforcement of the layer, the ceramic substrate is rotated in the copper bath with the ceramic side toward the anode that is mounted in the galvanic basin and rinsed with electrolyte. The vias are thus filled from the ceramic side. A further improvement in the mass exchange is made possible by using vibration and/or ultrasound. The vias are closed with copper particularly rapidly due to the more intense mass exchange.

1.-8. (canceled)

9. A method for producing a ceramic circuit board from a ceramic substrate having metal-filled vias, comprising the steps of
applying either a superficial copper metallization to one side of the ceramic substrate having vias by screen printing, or by binding a 100-300 μm copper film is on one side of the ceramic by the DCB/DBC method, and
filling the vias from the ceramic side by deposition of copper by an electro-galvanic process in a copper bath.

10. The method according to claim 9, wherein after applying the copper metallization by screen printing,
partially covering the copper metallization by an electroplate resist;
next filling the vias by the electro-galvanic process in a copper bath and at the same, the exposed sections which are not situated beneath the electroplate resist are reinforced to a layer thickness of 50-100 μm, and
next removing the electroplate resist chemically and dissolving the thinner unreinforced sections, which are provided with screen printing and were previously situated beneath the electroplate resist.

11. The method according to claim 9, wherein after bonding the copper film and filling the vias, any protruding copper burrs are removed mechanically, and then completing the ceramic substrates by using the DCB/DBC method.

12. The method according to claim 9, wherein the sections provided with the screen printing are dissolved with a mixture of HCl+FeCl₃.

13. The method according to claim 10, wherein the sections provided with the screen printing are dissolved with a mixture of HCl+FeCl₃.

14. The method according to claim 9, wherein the vias have a diameter of 50 to 5000 μm.

15. The method according to claim 10, wherein the vias have a diameter of 50 to 5000 μm.

16. The method according to claim 11, wherein the vias have a diameter of 50 to 5000 μm.

17. The method according to claim 12, wherein the vias have a diameter of 50 to 5000 μm.

18. The method according to claim 9, wherein the vias are created by lasering.

19. The method according to claim 10, wherein the vias are created by lasering.

20. The method according to claim 11, wherein the vias are created by lasering.

21. The method according to claim 12, wherein the vias are created by lasering.

22. The method according to claim 14, wherein the vias are created by lasering.

23. The method according to claim 9, wherein in the electro-galvanic process, the ceramic substrate is rotated in a the copper bath with the ceramic side facing the anode that is mounted in the galvanic basin, and the ceramic substrate is rinsed with electrolyte.

24. The method according to claim 10, wherein in the electro-galvanic process, the ceramic substrate is rotated in a the copper bath with the ceramic side facing the anode that is mounted in the galvanic basin, and the ceramic substrate is rinsed with electrolyte.

25. The method according to claim 9, wherein the mass exchange is improved via at least one member selected from the group consisting of vibration and ultrasound in the galvanic basin.

26. The method according to claim 10, wherein the mass exchange is improved via at least one member selected from the group consisting of vibration and ultrasound in the galvanic basin.

27. The method according to claim 11, wherein the mass exchange is improved via at least one member selected from the group consisting of vibration and ultrasound in the galvanic basin.

28. The method according to claim 12, wherein the mass exchange is improved via at least one member selected from the group consisting of vibration and ultrasound in the galvanic basin.
